(19) United States
(12) Patent Application Publication
(10) Pub. No.: US 2026/0047355 A1
(43) Pub. Date: Feb. 12, 2026

(54) METHOD OF MANUFACTURING SEMICONDUCTOR DEVICE

(71) Applicant: Mitsubishi Electric Corporation, Tokyo (JP)

(72) Inventor: Yasuhiro KIMURA, Tokyo (JP)

(73) Assignee: Mitsubishi Electric Corporation, Tokyo (JP)

(21) Appl. No.: 19/232,465

(22) Filed: Jun. 9, 2025

(30) Foreign Application Priority Data
Aug. 9, 2024 (JP) 2024-134172

(51) Int. Cl. H01L 21/02; C30B 25/18; C30B 29/36; C30B 33/00; H01L 21/04; H01L 21/304

(52) U.S. Cl. CPC H01L 21/02378; C30B 25/186; C30B 29/36; C30B 33/00; H01L 21/02634; H01L 21/0445; H01L 21/304

(57) ABSTRACT

The present disclosure has an object of providing a method of manufacturing a semiconductor device whose manufacturing processes can be simplified. The method of manufacturing the semiconductor device according to the present disclosure includes: a preparation process of preparing two crystalline substrates made of silicon carbide and having respective constant thicknesses; a laminating process of laminating the two crystalline substrates to form a laminated crystalline substrate; an epitaxial growth process of forming an epitaxial layer on a first main surface of the laminated crystalline substrate; an element forming process of forming an element on the epitaxial layer; and a grinding process of grinding, after the element forming process, the laminated crystalline substrate from a second main surface of the laminated crystalline substrate to grind an interface between the laminated two crystalline substrates, the second main surface facing the first main surface.

### BACKGROUND

### Technical Field

The present disclosure relates to a method of manufacturing a semiconductor device using silicon carbide.

### Description of the Background Art

Conventionally disclosed is a technology of manufacturing a semiconductor device by repeatedly using a single wafer source (see, for example, WO2022/059473).

Conventional manufacturing apparatuses that manufacture semiconductor devices each manufacture the semiconductor devices using a wafer with a constant thickness.

In WO2022/059473, a single wafer source is cut and ground using support members. Since the wafer source is reused through repetition of the cutting and grinding, each time the wafer source is used, the thickness of the wafer source varies. Thus, to make the most of the conventional manufacturing apparatuses, adjustment of each of the manufacturing apparatuses according to a thickness of a wafer source is necessary. This causes a problem of complicating manufacturing processes.

### SUMMARY

The present disclosure has an object of providing a method of manufacturing a semiconductor device whose manufacturing processes can be simplified.

A method of manufacturing a semiconductor device according to the present disclosure includes: a preparation process of preparing two crystalline substrates made of silicon carbide and having respective constant thicknesses; a laminating process of laminating the two crystalline substrates to form a laminated crystalline substrate; an epitaxial growth process of forming an epitaxial layer on a first main surface of the laminated crystalline substrate; an element forming process of forming an element on the epitaxial layer; and a grinding process of grinding, after the element forming process, the laminated crystalline substrate from a second main surface of the laminated crystalline substrate to grind an interface between the laminated two crystalline substrates, the second main surface facing the first main surface.

The present disclosure can simplify the manufacturing processes.

These and other objects, features, aspects, and advantages of the present disclosure will become more apparent from the following detailed description of the present disclosure when taken in conjunction with the accompanying drawings.

### BRIEF DESCRIPTION OF THE DRAWINGS

FIG. 1 illustrates a method of manufacturing a semiconductor device according to Embodiment 1;

FIG. 2 illustrates the method of manufacturing the semiconductor device according to Embodiment 1;

FIG. 3 illustrates the method of manufacturing the semiconductor device according to Embodiment 1;

FIG. 4 illustrates the method of manufacturing the semiconductor device according to Embodiment 1; and

FIG. 5 illustrates the method of manufacturing the semiconductor device according to Embodiment 1.

### DESCRIPTION OF THE PREFERRED EMBODIMENTS

### Embodiment 1

The following will describe a case where a wafer required for an element forming process (wafer process (WP)) that is a standard manufacturing process using a wafer made of silicon carbide (hereinafter abbreviated as “SiC”) and measuring six inches has a thickness of 350 μm and its final chip (a semiconductor device) has a thickness of 100 μm.

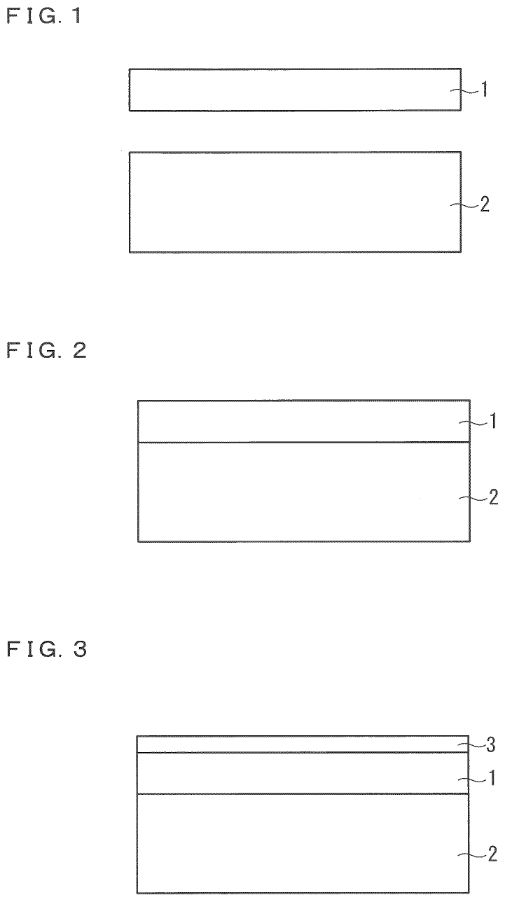

FIGS. 1 to 5 illustrate a method of manufacturing a semiconductor device according to Embodiment 1. The semiconductor device according to Embodiment 1 is a SiC semiconductor device.

First, a SiC single crystal substrate 1 and a SiC polycrystalline substrate 2, which are made of SiC and have respective constant thicknesses, are prepared in a preparation process in FIG. 1 Since the final chip has the thickness of 100 μm, the thickness of the SiC single crystal substrate 1 is defined as “100 μm+α”. Furthermore, since the wafer required for the element forming process (WP) has the thickness of 350 μm, the thickness of the SiC polycrystalline substrate 2 is defined as “250 μm−α”. Here, “α” is a margin for avoiding a concern that process variations of the SiC single crystal substrate 1 and process variations when the thickness of the whole wafer is changed to 100 μm after elements are formed cause a laminated interface between the SiC single crystal substrate 1 and the SiC polycrystalline substrate 2 to remain in a semiconductor device. “a” ranges, for example, from 5 to 10 μm.

Next, in a laminating process in FIG. 2, laminating the SiC single crystal substrate 1 to the SiC polycrystalline substrate 2 forms a laminated crystalline substrate. In FIG. 2, the laminated crystalline substrate has a thickness of 350 μm.

Next, in an epitaxial growth process in FIG. 3, an epitaxial layer 3 is formed on the first main surface (the SiC single crystal substrate 1) of the laminated crystalline substrate.

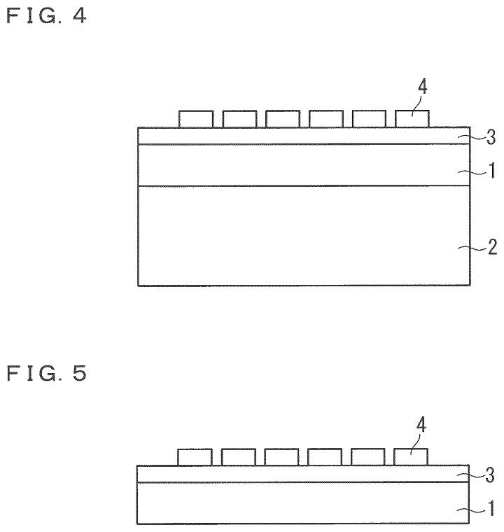

Next, in an element forming process in FIG. 4, elements 4 are formed on the epitaxial layer 3.

Next, in a grinding process in FIG. 5, the laminated crystalline substrate is ground from the second main surface (the SiC polycrystalline substrate 2) of the laminated crystalline substrate which faces the first main surface, until the semiconductor device has the final thickness of 100 μm. Here, the laminated interface between the SiC single crystal substrate 1 and the SiC polycrystalline substrate 2 is also ground. The wafer after the grinding process includes the SiC single crystal substrate 1, the epitaxial layer 3, and the elements 4.

Then, performing a dicing process on the ground wafer completes the semiconductor device.

### Advantages

In Embodiment 1, the laminated crystalline substrate obtained by laminating the SiC single crystal substrate 1 to the SiC polycrystalline substrate 2 has a constant thickness (350 μm). Since there is no need to adjust a manufacturing apparatus according to a thickness of a wafer source unlike WO2022/059473, the manufacturing processes of the semiconductor device can be simplified.

When the SiC single crystal substrate 1 is laminated onto the SiC polycrystalline substrate 2, voids are generated in the interface between the substrates. Voids in a semiconductor device inhibit a current flowing through the semiconductor device, and increases the ON resistance of the semiconductor device. Even when a semiconductor device passes a shipping inspection due to a little influence on an increase in the ON resistance, repeated increase/decrease in temperature when using the semiconductor device places a significant stress on the semiconductor device. Thus, there is a concern that the laminated interface may be split from a void as a starting point and the semiconductor device may be damaged. As such, there is a concern that voids in the semiconductor device may reduce yields of the semiconductor devices and reduce the reliability of elements. Since the laminated interface between the SiC single crystal substrate 1 and the SiC polycrystalline substrate 2 is ground in the grinding process in Embodiment 1, there is no void in the ground semiconductor device. Thus, concerns about decreases in yields of the semiconductor devices and decreases in the reliability of elements can be avoided.

In Embodiment 1, the laminated crystalline substrate obtained by laminating the SiC single crystal substrate 1 to the SiC polycrystalline substrate 2 is ground. Thus, the manufacturing processes of the semiconductor device can be simplified when compared to the grinding process in WO2022/059473 which is performed after the wafer source is cut.

Embodiments of the present disclosure can be appropriately modified or omitted within the scope of the present disclosure.

### APPENDIXES

A summary of various aspects of the present disclosure will be hereinafter described as Appendixes.

### Appendix 1

A method of manufacturing a semiconductor device, the method comprising:
a preparation process of preparing two crystalline substrates made of silicon carbide and having respective constant thicknesses;
a laminating process of laminating the two crystalline substrates to form a laminated crystalline substrate;
an epitaxial growth process of forming an epitaxial layer on a first main surface of the laminated crystalline substrate;
an element forming process of forming an element on the epitaxial layer; and
a grinding process of grinding, after the element forming process, the laminated crystalline substrate from a second main surface of the laminated crystalline substrate to grind an interface between the laminated two crystalline substrates, the second main surface facing the first main surface.

### Appendix 2

The method according to appendix 1,
wherein the two crystalline substrates are a single crystal substrate and a polycrystalline substrate.

### Appendix 3

The method according to appendix 2,
wherein the epitaxial layer is formed on the single crystal substrate.

### Appendix 4

The method according to appendix 2 or 3,
wherein the single crystal substrate has a thickness of 100 μm or more,
the polycrystalline substrate has a thickness of 250 μm or less, and
the laminated crystalline substrate has a thickness of 350 μm.

While the disclosure has been shown and described in detail, the foregoing description is in all aspects illustrative and not restrictive. It is therefore understood that numerous modifications and variations can be devised.

What is claimed is:

1. A method of manufacturing a semiconductor device, the method comprising:
a preparation process of preparing two crystalline substrates made of silicon carbide and having respective constant thicknesses;
a laminating process of laminating the two crystalline substrates to form a laminated crystalline substrate;
an epitaxial growth process of forming an epitaxial layer on a first main surface of the laminated crystalline substrate;
an element forming process of forming an element on the epitaxial layer; and
a grinding process of grinding, after the element forming process, the laminated crystalline substrate from a second main surface of the laminated crystalline substrate to grind an interface between the laminated two crystalline substrates, the second main surface facing the first main surface.

2. The method according to claim 1,
wherein the two crystalline substrates are a single crystal substrate and a polycrystalline substrate.

3. The method according to claim 2,
wherein the epitaxial layer is formed on the single crystal substrate.

4. The method according to claim 2,
wherein the single crystal substrate has a thickness of 100 μm or more,
the polycrystalline substrate has a thickness of 250 μm or less, and
the laminated crystalline substrate has a thickness of 350 μm.

5. The method according to claim 3,
wherein the single crystal substrate has a thickness of 100 μm or more,
the polycrystalline substrate has a thickness of 250 μm or less, and
the laminated crystalline substrate has a thickness of 350 μm.
